(19) United States
(12) Patent Application Publication
(10) Pub. No.: US 2026/0287701 A1
(43) Pub. Date: Sep. 24, 2026

(54) SYSTEM AND METHOD OF VALIDATING READINGS OF AN ENERGY METER

(71) Applicant: Honeywell International Inc., Charlotte, NC (US)

(72) Inventors: Ashwini Mahato, Bangalore (IN); Jayalaxmi Telang, Bangalore (IN)

(21) Appl. No.: 19/085,091

(22) Filed: Mar. 20, 2025

(51) Int. Cl. G01R 35/04; G01R 22/06; H02J 3/00

(52) U.S. Cl. CPC G01R 35/04; G01R 22/068; H02J 3/003

(57) ABSTRACT

A method and system for validating power consumption is disclosed. The method includes identifying, for a facility, a utility meter, one or more facility meters, and at least one transformer. The transformer connects the utility meter to each facility meter, and each facility meter is connected to one or more loads. The method includes retrieving the accuracy class of each facility meter and power consumption recorded by the facility meters. Additionally, parameters associated with the transformer are retrieved to compute transformer losses. The method includes determining facility power consumption for a predetermined period based on factors including power consumption recorded by facility meters, transformer losses, and errors, including accuracy class errors of facility meters and transformers. Further, power consumption recorded by the utility meter is retrieved for the same period and a comparison between facility consumption and utility meter records is generated, and stored for validation and management.

### FIELD OF INVENTION

The present invention generally relates to energy management. More specifically, the present invention is related to a system and a method of validating readings of an energy meter.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also correspond to implementations of the claimed technology.

Accurate measurement and billing of electricity consumption are essential for both utility service providers and consumers. Typically, energy consumption in facilities including industrial plants, commercial buildings, and residential complexes is monitored by the utility provider through utility meters. The utility meters are typically located at the utility service provider side, after a utility grid that supplies a main supply power. The utility meters record the total electricity supplied to the facility and serve as the basis for billing by the utility service providers.

Additionally, facility meters are installed within the facility to monitor individual consumption by specific loads or sections or consumers. However, there are often discrepancies between the readings of the utility meter and the aggregate readings from the facility meters. One critical issue is that consumers do not have access to the utility meter readings until a bill is raised by the utility service provider. This lack of real-time access means that consumers are unaware of their actual recorded consumption until they receive their utility bill.

Consequently, if a fault or inaccuracy occurs in the utility meter, the consumer has no way of detecting it in advance or validating the bill when it is issued. They are left relying solely on the measurement provided in the utility bill, with no independent means to verify its accuracy. In such situations, discrepancies can lead to overbilling or underbilling. If the utility meter records more energy than was consumed due to a fault or malfunction, the consumer may be unfairly charged for excess consumption. Conversely, underbilling due to a fault affects the utility provider's revenue.

The discrepancies between the readings of the utility meter and facility meters occur due to several reasons including but not limited to, energy losses in transformers. Transformers are not perfectly efficient, and energy is lost during the conversion process. Additionally, since transformer losses are rarely accounted for in standard billing procedures, the aggregated facility meter readings may not match the utility meter readings even under normal operating conditions.

The lack of a mechanism to cross-verify utility meter readings with facility meter data leaves consumers vulnerable to billing errors. Without transparency in the measurement process and a means to independently validate energy consumption, consumers have little recourse if they suspect inaccuracies. This situation can lead to disputes, financial strain, and a lack of trust in the billing process. As energy management and efficiency become increasingly critical, the need for accurate energy consumption monitoring and billing grows. Facilities rely on precise energy data to optimize their operations, reduce costs, and enhance efficiency. Without a method to validate utility meter readings against facility meter data and account for potential sources of error, consumers are left vulnerable to inaccurate billing and undetected faults. Therefore, there is a clear and urgent need for a system and a method to validate power consumption.

### SUMMARY OF THE INVENTION

This summary is provided to introduce aspects related to a method for validating power consumption and the aspects are further described below in the detailed description. This summary is not intended to identify essential features of the claimed subject matter nor is it intended for use in determining or limiting the scope of the claimed subject matter.

In an embodiment of the present disclosure, a method for validating power consumption is disclosed. The method includes steps of identifying for a facility, a utility meter, one or more facility meters, and at least one transformer. The transformer connects the utility meter to each facility meter, and each facility meter is connected to one or more loads. The method further includes a step of retrieving an accuracy class of each of the facility meters, and power consumption recorded by the one or more facility meters. Further, the method includes a step of retrieving one or more parameters associated with the transformer to compute losses associated with the transformer.

Furthermore, the method includes a step of determining power consumption of the facility for a predetermined time period, based on factors including power consumption recorded by the facility meters, the losses associated with the transformer and one or more errors including accuracy class errors of each facility meter based on loads, and accuracy class errors associated with the transformer. The method further includes a step of retrieving power consumption recorded by the utility meter for the predetermined time period. Further, the method includes a step of generating a comparison between the power consumption of the facility and the power consumption recorded by the utility meter for the predetermined time period. The method includes a step of storing the comparison for validating and managing power consumption at the facility.

In an aspect of the present disclosure, the power consumption recorded by the facility meters includes at least one of active power consumption and apparent power consumption of the loads connected to the facility meters and power factors of the loads.

In an aspect of the present disclosure, the accuracy class errors of the facility meters are calculated based on the active power consumption of the loads and the accuracy class of each of the facility meters.

In an aspect of the present disclosure, the one or more parameters associated with the transformer include at least one of transformer type, accuracy class of the transformer, number of transformers, and loading of the transformer.

In an aspect of the present disclosure, the losses associated with the transformer are calculated based on losses of the transformer on no load, full load, and partial load.

In an aspect of the present disclosure, the one or more errors further include one or more of measurement errors, calibration errors, voltage errors, waveform sampling errors, and phase shift errors.

In an aspect of the present disclosure, the accuracy class of the facility meters, and the transformer are pre-defined.

In an aspect of the present disclosure, the method includes a step of detecting a fault in operation of the utility meter upon determining a difference in the power consumption recorded by the utility meter and the power consumption of the facility for the predetermined time period.

In an aspect of the present disclosure, the method includes a step of predicting future power consumption by the one or more loads, using the power consumption of the facility for the predetermined time period.

In an embodiment of the present disclosure, a system for validating power consumption is disclosed. The system includes a processor and a memory coupled with the processor. The memory stores program instructions configured to identify a utility meter, one or more facility meters, and at least one transformer for a facility. The transformer connects the utility meter to each facility meter, and each facility meter is connected to one or more loads. The memory further stores program instructions configured to retrieve an accuracy class of each of the facility meters, and power consumption recorded by the one or more facility meters. Further, the memory stores program instructions configured to retrieve one or more parameters associated with the transformer to compute losses associated with the transformer.

Furthermore, the memory stores program instructions configured to determine power consumption of the facility for a predetermined time period, based on factors including power consumption recorded by the one or more facility meters, the losses associated with the transformer and one or more errors including accuracy class errors of each facility meter based on loads, and accuracy class errors associated with the transformer. The memory further stores program instructions configured to retrieve power consumption recorded by the utility meter for the predetermined time period. The memory further stores program instructions configured to generate a comparison between the power consumption of the facility and the power consumption recorded by the utility meter for the predetermined time period. Further, the memory stores program instructions configured to store the comparison to validate and manage power consumption at the facility.

In an aspect of the present disclosure, the power consumption recorded by the facility meters includes at least one of active power consumption and apparent power consumption of the loads connected to the facility meters, and power factors of the loads.

In an aspect of the present disclosure, the accuracy class errors of the facility meters are calculated based on the active power consumption of the loads and an accuracy class of each of the facility meters.

In an aspect of the present disclosure, the one or more parameters associated with at least one transformer include at least one of transformer type, accuracy class of the transformer, number of transformers, and loading of the transformer.

In an aspect of the present disclosure, the losses associated with the transformer are calculated based on losses of the transformer on no load, full load, and partial load.

In an aspect of the present disclosure, the one or more errors further include one or more of measurement errors, calibration errors, voltage errors, and phase shift errors.

In an aspect of the present disclosure, the accuracy class of the facility meters, and the transformer are pre-defined.

In an aspect of the present disclosure, the memory further stores program instructions configured to detect a fault in operation of the utility meter upon determining a difference in the power consumption recorded by the utility meter and the power consumption of the facility for the predetermined time period.

In an aspect of the present disclosure, the memory further stores program instructions configured to predict future energy consumptions by the one or more loads, using the power consumption of the facility for the predetermined time period.

In one embodiment, a non-transitory computer-readable storage medium for validating power consumption is disclosed. The non-transitory computer-readable storage medium comprises a computer program code for execution by one or more processors of an apparatus. The computer program code is configured to, when executed by the one or more processors, cause the apparatus to identify a utility meter, one or more facility meters, and at least one transformer for a facility. The transformer connects the utility meter to each facility meter, and each facility meter is connected to one or more loads. The computer program code is further configured to cause the apparatus to retrieve an accuracy class of each of the facility meters, and power consumption recorded by the one or more facility meters. The computer program code is further configured to cause the apparatus to retrieve one or more parameters associated with the transformer to compute losses associated with the transformer.

The computer program code is further configured to cause the apparatus to determine power consumption of the facility for a predetermined time period, based on factors including power consumption recorded by the facility meters, the losses associated with the transformer and one or more errors including accuracy class errors of each facility meter based on loads, and accuracy class errors associated with the transformer. The computer program code is further configured to cause the apparatus to retrieve power consumption recorded by the utility meter for the predetermined time period. The computer program code is further configured to cause the apparatus to generate a comparison between the power consumption of the facility and the power consumption recorded by the utility meter for the predetermined time period. The computer program code is further configured to cause the apparatus to store the comparison to validate and manage power consumption at the facility.

In an aspect of the present disclosure, the losses associated with the transformer are calculated based on losses of the transformer on no load, full load, and partial load.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying drawings constitute a part of the description and are used to provide a further understanding of the present disclosure. In the drawings:

FIG. 1 illustrates a network connection diagram of a system for validating power consumption, in accordance with an embodiment of the present disclosure;

FIG. 2 illustrates a block diagram of an example computing device for validating power consumption, in accordance with an embodiment of the present disclosure;

FIG. 3 illustrates a block diagram of the computing device comprising program instructions for validating power consumption, in accordance with an embodiment of the present disclosure;

FIG. 4 illustrates an event diagram of the system for validating power consumption, in accordance with an embodiment of the present disclosure;

FIG. 5 illustrates error calculations for a predetermined time, in accordance with an embodiment of the present disclosure;

FIG. 6 illustrates a summary of the error calculations for the predetermined time, in accordance with an embodiment of the present disclosure; and

FIGS. 7A and 7B cumulatively illustrate a flow chart of a method for validating power consumption, in accordance with an embodiment of the present disclosure.

A more complete understanding of the present invention and its embodiments thereof may be acquired by referring to the following description and the accompanying drawings.

### DETAILED DESCRIPTION OF THE INVENTION

Exemplary embodiments now will be described with reference to the accompanying drawings. The disclosure may, however, be embodied in many different forms and should not be construed as limited to the embodiments set forth herein; rather, these embodiments are provided so that this disclosure will be thorough and complete, and will fully convey its scope to those skilled in the art. The terminology used in the detailed description of the particular exemplary embodiments illustrated in the accompanying drawings is not intended to be limiting. In the drawings, like numbers refer to like elements.

It is to be noted, however, that the reference numerals used herein illustrate only typical embodiments of the present subject matter, and are therefore, not to be considered for limiting its scope, for the subject matter may admit to other equally effective embodiments.

The detailed description includes specific details for the purpose of providing a thorough understanding of the present invention. However, it will be apparent to those skilled in the art that the present invention may be practiced without these specific details.

In modern power management systems and methods, accurately monitoring and validating energy consumption is critical for efficient operations and cost management. To address discrepancies in energy consumption data and ensure accurate monitoring, the present invention introduces a system and a method for validating power consumption. By identifying key components and retrieving parameters such as accuracy classes and power consumption metrics, the method calculates transformer losses and other associated errors to provide a reliable comparison between recorded and actual power consumption.

The method involves determining the power consumption of a facility for a specified time period by considering various factors, including the active and apparent power consumption recorded by facility meters, transformer losses, and errors like accuracy class and calibration discrepancies. By retrieving power consumption data from the utility meter and comparing it with the calculated facility consumption, this approach enables precise validation. Furthermore, any inconsistencies detected between the data of a utility meter and facility-level calculations can identify faults in operation of the utility meter.

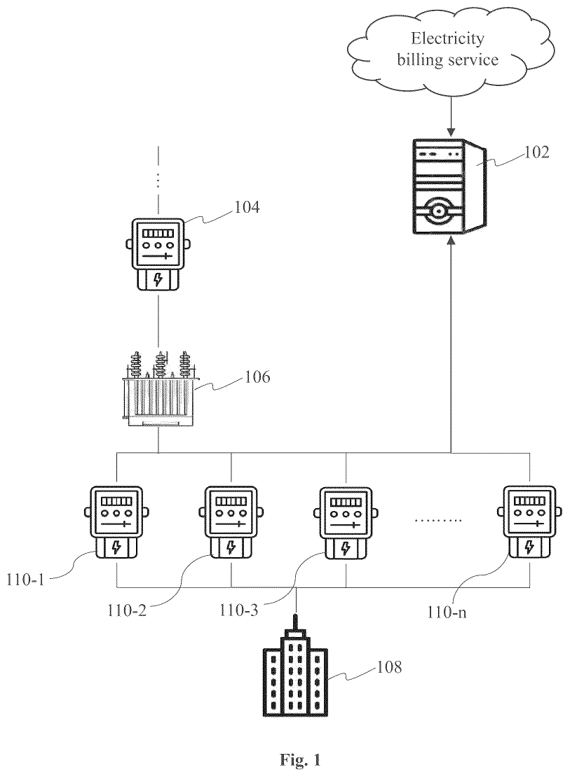

FIG. 1 illustrates a network connection diagram of a system 102 for validating power consumption, in accordance with an embodiment of the present invention. The system 102 may be a data processing device such as a server. In an embodiment, the server may be implemented over a cloud network. In another embodiment, the server may be a physical server.

As shown in the FIG. 1, a utility meter 104 may monitor consumption of a main supply power from a utility grid of a service provider. The main supply power is typically delivered at high voltage and is unsuitable for direct use within a facility/infrastructure. To address the high voltage, at least one transformer 106 may perform step-down operation on the main supply power to distribute electrical power to a facility 108. The step-down operation of a transformer refers to the process of reducing the voltage level from a higher value to a lower value while maintaining frequency. For validating power consumption of the facility 108, the system 102 may be configured to identify one or more utility meter 104, one or more facility meters 110, and at least one transformer for the facility 108.

In an embodiment, the facility 108 may include a plurality of types of premises where energy consumption may be monitored and managed. The facility 108 may include but is not limited to, industrial sites including manufacturing plants, factories, refineries, and power generation plants. The facility 108 may include but is not limited to, commercial facilities, including office buildings, shopping malls, data centres, and hotels. The facility 108 may include but is not limited to, residential facilities, including apartment complexes and large housing societies. Additionally, the facility 108 may include but is not limited to, institutional facilities including hospitals, schools, and research laboratories. Further, the facility 108 may include but is not limited to, public utilities and infrastructure facilities, including airports, railway stations, and water treatment plants. Other examples may include agricultural facilities like farms and greenhouses, recreational and entertainment venues such as stadiums and amusement parks, and defence facilities like army bases and naval stations.

Further, one or more facility meters 110-1 to 110-n (collectively referred to as 110) may be connected to one or more electrical loads in the facility 108. The facility meters 110 may be distributed throughout the facility 108 to monitor energy consumption. The facility meters 110 may be configured to capture power consumption of the one or more loads, including but not limited to, working power consumption, apparent power consumption, and power factors of the electrical loads. Further, the system 102 may be communicatively connected to the facility meters 110.

In an embodiment, the system 102 may communicate with the facility meters 110 in the facility 108 through a building management system (BMS). The BMS may be installed at the facility to monitor and transfer the electrical parameters to the system 102. The BMS may further transfer loading data from the transformer 106. In one embodiment, the BMS may be installed in the system 102.

In another embodiment, the BMS may be an integrated system designed to monitor, control, and optimize building operations, including electrical systems, HVAC (heating, ventilation, and air conditioning), lighting, security, fire safety, and energy management. The BMS provides centralized control and real-time data insights associated with the facility 108. The BMS may typically comprise sensors, controllers, communication networks, and software that facilitate automation and decision-making processes.

In another embodiment, the system 102 may communicate with a building management system and the facility meters 110 in the facility 108 through a communication network. The communication network may be a wired and/or a wireless network. The communication network may be implemented using communication techniques such as Visible Light Communication (VLC), Worldwide Interoperability for Microwave Access (WiMAX), Long Term Evolution (LTE), Wireless Local Area Network (WLAN), Infrared (IR) communication, Public Switched Telephone Network (PSTN), Radio waves, and other communication techniques known in the art.

The communication network may utilize network components to establish connection among the system 102, and the facility. The network components may include, hubs, switches, routers, bridges, and repeaters. The routers may be of different types such as Provide Edge (PE) routers, Customer Edge (CE) routers, and intermediate routers.

Upon identifying the utility meter 104, one or more facility meters 110, and at least one transformer for the facility 108, the system 102 may be configured to retrieve an accuracy class of each of the facility meters 110, and power consumption recorded by the one or more facility meters 110. Furthermore, the power consumption recorded by the facility meters 110 may include but is not limited to, at least one of the active power consumption, the apparent power consumption of the electrical loads connected to the facility meters 110, and the power factors of the electrical loads. Further, the system 102 may retrieve waveform sampling rate of the facility meters 110. The accuracy class and the waveform sampling rate of the facility meters 110 may be pre-defined.

In an embodiment, one or more sensors may be connected to the one or more facility meters 110. The sensor connected to the facility meters 110 may be configured to detect and transfer data associated with working power consumption, apparent power consumption, and power factors of one or more electrical loads connected to the one or more facility meters 110.

Upon retrieving the accuracy class of each of the facility meters 110, and power consumption recorded by the one or more facility meters 110, the system 102 may be configured to retrieve one or more parameters associated with the transformer 106 to compute losses associated with the transformer 106. In an embodiment, one or more sensors may be connected to the transformer 106. The sensor connected to the transformer 106 may be configured to detect and transfer one or more parameters associated with transformer 106. The one or more parameters associated with at least one transformer 106 may include but are not limited to at least one of, transformer type, accuracy class of the transformer, number of transformers, and loading of the transformer 106.

Once the parameters associated with the transformer 106 are retrieved, the system 102 may calculate losses associated with the transformer 106, that occur during the conversion of high-voltage main supply power to the electrical power (lower-voltage power) for distribution. The losses associated with the transformer 106 may be calculated based on losses of the transformer on no load, full load, and partial load.

Upon retrieving the one or more parameters associated with the transformer 106 and calculating the losses associated with the transformer 106, the system 102 may be configured to determine power consumption of the facility 108 for a predetermined time period. The power consumption of the facility 108 for the predetermined time period may be determined based on factors including power consumption recorded by the one or more facility meters 110, the losses associated with the transformer 106, and one or more errors including accuracy class errors of each facility meter 110 based on different loads, and accuracy class errors associated with the transformer 106.

Further, the power consumption of the facility 108 may be determined by incorporating the losses associated with the transformer 106, and the one or more errors in the power consumption recorded by the one or more facility meters 110 for the predetermined time period. The one or more errors further include one or more of, measurement errors, calibration errors, voltage imbalance errors, waveform sampling errors, and phase shift errors. Further, the measurement errors may occur due to limitations in precision of the facility meters and transformers, and may include the accuracy class errors of the transformer 106 and the facility meters 110. Further, in accordance with the present invention, the accuracy class errors of the facility meters 110 may be calculated based on the active power consumption of the loads and the accuracy class of each of the facility meters 110.

In an embodiment, the sensor connected to the transformer 106 may have one or more accuracy class errors. Furthermore, the sensor connected to the facility meters 110 may have one or more accuracy class errors. Further, the accuracy class errors of the sensors may also be incorporated in the power consumption recorded by the facility meters 110, while determining the power consumption of the facility 108.

Once the power consumption of the facility 108 is determined, the system 102 may be configured to retrieve power consumption recorded by the utility meter 104 for the predetermined time period. The power consumption recorded by the utility meter 104 may be fetched via servers of electricity billing service (as shown in FIG. 1), or one or more electricity bills, or may be fetched manually if a user of the system 102 has access to the utility meter 104.

After retrieving the power consumption recorded by the utility meter 104 for the predetermined time period, the system 102 may be configured to generate a comparison between the power consumption of the facility 108 and the power consumption recorded by the utility meter 104 for the predetermined time period. Further, the system 102 may be configured to store the comparison to validate and manage the power consumption at the facility 108.

The system 102 may be further configured to detect a fault in operation of the utility meter 104 upon determining a difference in the power consumption recorded by the utility meter 104 and the power consumption of the facility 108 for the predetermined time period.

In an embodiment, the system 102 may further be configured to predict future energy consumptions by the one or more loads in the facility 108, using the power consumption of the facility 108 for the predetermined time period.

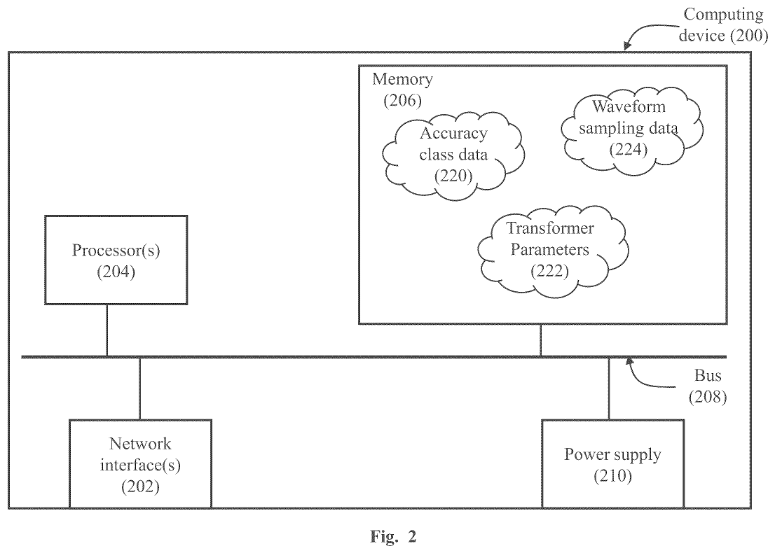

FIG. 2 illustrates a block diagram of an example computing device 200 (similar to the system 102) for validating power consumption, in accordance with an embodiment of the present disclosure. The computing device 200 may be implemented remotely over a cloud network or locally. The computing device 200 may comprise one or more network interfaces 202 (e.g., wired, wireless, etc.), at least one processor 204, a memory 206 interconnected by a system bus 208, and a power supply 210.

The one or more network interfaces 202 may be used to provide input or fetch output from the computing device 200. The one or more network interfaces 202 may be implemented as a Command Line Interface (CLI) or a Graphical User Interface (GUI). Further, Application Programming Interfaces (APIs) may also be used for remotely interacting with edge systems and cloud servers.

The processor 204 may include one or more general purpose processors (e.g., INTEL® or Advanced Micro Devices® (AMD) microprocessors) and/or one or more special purpose processors (e.g., digital signal processors or Xilinx® System On Chip (SOC) Field Programmable Gate Array (FPGA) processor), MIPS/ARM-class processor, a microprocessor, a digital signal processor, an application specific integrated circuit, a microcontroller, a state machine, or any type of programmable logic array.

The memory 206 may include, but is not limited to, non-transitory machine-readable storage devices such as hard drives, magnetic tape, floppy diskettes, optical disks, Compact Disc Read-Only Memories (CD-ROMs), and magneto-optical disks, semiconductor memories, such as ROMs, Random Access Memories (RAMs), Programmable Read-Only Memories (PROMs), Erasable PROMs (EPROMs), Electrically Erasable PROMs (EEPROMs), flash memory, magnetic or optical cards, or other type of media/machine-readable medium suitable for storing electronic instructions.

The memory 206 may include a plurality of storage locations that are addressable by the processor 204 and the network interfaces 202 for storing software programs and other necessary information (accuracy class data 220, transformer parameter data 222 and waveform sampling data 224) associated with the embodiments described herein. The processor 204 may comprise hardware elements or hardware logic adapted to execute the software programs and manipulate data structures.

It will be apparent to those skilled in the art that other processor and memory types, including various computer-readable media, may be used to store and execute program instructions pertaining to the techniques described herein. Also, while the description illustrates various processes, it is expressly contemplated that various processes may be embodied as modules configured to operate in accordance with the techniques herein (e.g., according to the functionality of a similar process). Further, while the processes have been shown separately, those skilled in the art will appreciate that processes may be routines or modules within other processes.

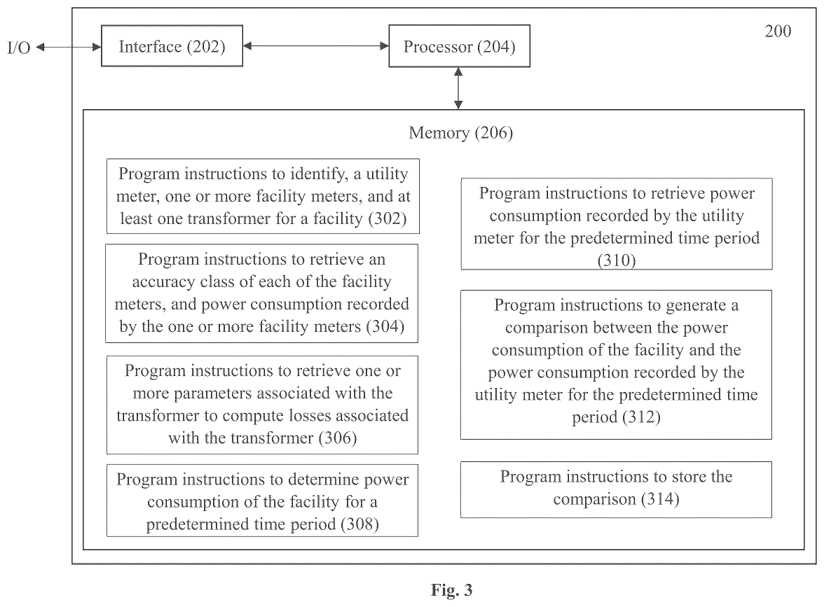

FIG. 3 illustrates a block diagram of the computing device 200 comprising program instructions for determining asset context equivalence, in accordance with an embodiment of the present disclosure. The memory 206 of the computing device 200 may store program instructions for performing several functions associated with prediction of the key event. Functional code stored in the memory 206 may include program instructions to identify a utility meter, one or more facility meters, and at least one transformer for a facility 302, program instructions to retrieve an accuracy class of each of the facility meters, and power consumption recorded by the one or more facility meters 304, program instructions to retrieve one or more parameters associated with the transformer to compute losses associated with the transformer 306, program instructions to determine power consumption of the facility for a predetermined time period 308, program instructions to retrieve power consumption recorded by the utility meter for the predetermined time period 310, program instructions to generate a comparison between the power consumption of the facility and the power consumption recorded by the utility meter for the predetermined time period 312, and program instructions to store the comparison to validate and manage power consumption at the facility 314.

The program instructions to identify a utility meter, one or more facility meters, and at least one transformer for a facility 302 may cause the processor 204 to identify a utility meter, one or more facility meters, and at least one transformer for a facility. The transformer connects the utility meter to each facility meter, and each facility meter is connected to one or more loads.

The program instructions to retrieve an accuracy class of each of the facility meters, and power consumption recorded by the one or more facility meters 304, may cause the processor 204 to retrieve an accuracy class of each of the facility meters, and power consumption recorded by the one or more facility meters.

The program instructions to retrieve one or more parameters associated with the transformer to compute losses associated with the transformer 306 may cause the processor 204 to retrieve one or more parameters associated with the transformer to compute losses associated with the transformer to compute losses associated with the transformer. The one or more parameters associated with at least one transformer may include but are not limited to at least one of, transformer type, accuracy class of the transformer, number of transformers, and loading of the transformer.

The program instructions to determine power consumption of the facility for a predetermined time period 308 may cause the processor 204 to determine power consumption of the facility for a predetermined time period, based on factors including power consumption recorded by the one or more facility meters 110, the losses associated with the transformer 106, and one or more errors including accuracy class errors of each facility meter 110 based on different loads, and accuracy class errors associated with the transformer 106. Further, the power consumption of the facility 108 may be determined by incorporating the losses associated with the transformer 106, and the one or more errors in the power consumption recorded by the one or more facility meters 110 for the predetermined time period. The one or more errors further include one or more of, measurement errors, calibration errors, voltage imbalance errors, waveform sampling errors, and phase shift errors.

The program instructions to retrieve power consumption recorded by the utility meter for the predetermined time period 310 may cause the processor 204 to retrieve power consumption recorded by the utility meter. The power consumption recorded by the utility meter may be fetched via servers of electricity billing service, or one or more electricity bills, or may be fetched manually if a user of the computing device 200 has access to the utility meter.

Additionally, program instructions to generate a comparison between the power consumption of the facility and the power consumption recorded by the utility meter for the predetermined time period 312, may cause the processor 204 to generate a comparison between the power consumption of the facility and the power consumption recorded by the utility meter for the predetermined time period. Furthermore, the program instructions to store the comparison to validate and manage power consumption at the facility 314 may cause the processor 204 to store the comparison to validate and manage power consumption at the facility. The comparison may be stored in the memory 206.

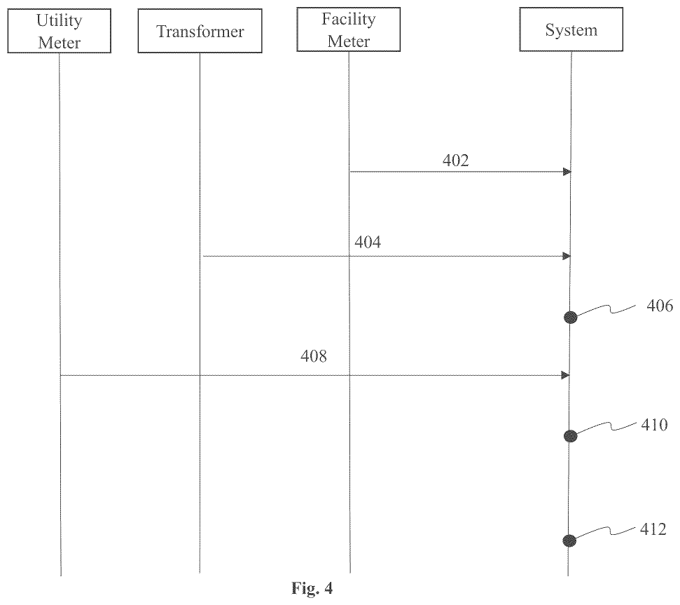

FIG. 4 illustrates an event diagram of the system 102 for validating power consumption, in accordance with an embodiment of the present disclosure. The order in which events are described is not intended to be construed as a limitation, and any number of the described events can be combined in any order to validate power consumption. Additionally, individual events may be deleted from the event diagram without departing from the scope of the subject matter described herein.

Once the utility meter 104, one or more facility meters 110, and at least one transformer are identified for the facility 108, following events may occur for validating power consumption of the facility 108. In event 402, the system 102 may retrieve an accuracy class of each of the facility meters 110, and power consumption recorded by the one or more facility meters 110. Further, the system 102 may retrieve waveform sampling rate of the facility meters 110. The accuracy class and the waveform sampling rate of the facility meters 110 may be pre-defined.

The accuracy class of a meter may refer to a predefined standard that specifies one or more permissible error limits of the meter under specified operating conditions. The accuracy class represents a precision with which the meter measures electrical parameters including voltage, current, power, or energy consumption. The accuracy class is typically denoted as a percentage (e.g., 0.2, 0.5, or 1.0), indicating the maximum allowable deviation between the measured value and the true value as a percentage of the latter. For example, a meter with an accuracy class of 0.5 has a maximum permissible error of ±0.5% under standard operating conditions.

Further, the power consumption recorded by the facility meters 110 may include but is not limited to, at least one of the active power consumption, the apparent power consumption of the electrical loads connected to the facility meters 110, and the power factors of the electrical loads. The active power consumption, also known as working power, is the actual power consumed by the electrical loads to work. The active power consumption is measured in watts (W) or kilowatts (kW) and represents the real energy transferred and utilized in an electrical system. Further, apparent power consumption is total power flowing in an electrical circuit, combining both active power and reactive power. The apparent power consumption is measured in volt-amperes (VA) or kilovolt-amperes (kVA).

Furthermore, the apparent power reflects the total capacity required to supply both the useful power and the energy stored in the system due to inductive or capacitive loads. Lastly, the power factor is the ratio of active power to apparent power in an electrical system. The power factor indicates the efficiency with which electrical power is converted into useful work. A power factor value ranges from 0 to 1, with higher values indicating greater efficiency. The power factor is influenced by the type of load and the phase angle between voltage and current.

Reactive power mentioned above is a component of electrical power that oscillates between a source and reactive elements, including inductors and capacitors, in an Alternating-Current (AC) system. The reactive power does not perform any useful work but is necessary for maintaining the voltage levels and magnetic fields required for the proper operation of inductive or capacitive loads, including motors or transformers. Reactive power is measured in reactive volt-amperes (VAR).

The relationship between the active, reactive, and apparent power may be visualized using a power triangle, wherein the active power forms the horizontal axis, the reactive power forms the vertical axis, and the apparent power is the hypotenuse. The power factor, as mentioned earlier, is the cosine of the angle between active power and apparent power, indicating the efficiency of power usage in the system.

In event 404, the system 102 may be configured to retrieve one or more parameters associated with the transformer 106 to compute losses associated with the transformer 106. The one or more parameters associated with at least one transformer 106 may include but are not limited to at least one of, transformer type, accuracy class of the transformer, number of transformers, and loading of the transformer 106.

The type of transformer may include, but is not limited to, step-up, step-down, isolation, autotransformers, distribution transformers, oil-transformers, and smart transformers. The type of transformer may determine function of the transformer within an energy network and also affects how the transformer interacts with other components in the system. The accuracy class of the transformer specifies one or more permissible error limits for voltage or current transformation under standard conditions.

Additionally, the number of transformers in the energy network may be a key parameter, as it affects the load distribution and overall energy losses. Multiple transformers may be used in parallel or series configurations, depending on the power demands and operational requirements of the facility 108.

The loading of the transformer may also be an important consideration, representing the proportion of the load relative to a rated capacity of the transformers. The loading of the transformer may include variations in load conditions over time, real-time loading percentage, and the nature of the load, such as resistive or inductive. Further, the losses may include core losses (no-load losses) and copper losses (load-dependent losses), both of which depend on the design, loading conditions, and operating environment of the transformer 106. Further, the parameters associated with the transformer 106 may include waveform sampling rate of the transformer. The accuracy class and the waveform sampling rate of the transformer 106 may be pre-defined.

Further, the losses associated with the transformer 106, that occur during the conversion of high-voltage main supply power to the electrical power (lower-voltage power) for distribution may be calculated using the formula:

$${P}_{Total} = {P}_{No - Load} + {( \% Load )}^{2} \times {P}_{Load} , \qquad ( eq . 1 )$$

In the above equation (eq. 1), P_{Total} may be the losses associated with the transformer 106, P_{No-Load} may be loss when the transformer 106 is idle (no load), P_{Load} may be loss when the transformer 106 is under full load, and % Load may be partial capacity of the transformer 106 being utilized.

In event 406, the system 102 may be configured to determine power consumption of the facility 108 for a predetermined time period. The power consumption of the facility 108 for the predetermined time period may be determined based on factors including power consumption recorded by the one or more facility meters 110, the losses associated with the transformer 106, and one or more errors including accuracy class errors of each facility meter 110 based on different loads, and accuracy class errors associated with the transformer 106.

Further, the power consumption of the facility 108 may be determined by incorporating the losses associated with the transformer 106, and the one or more errors in the power consumption recorded by the one or more facility meters 110 for the predetermined time period. The one or more errors further include one or more of, measurement errors, calibration errors, voltage imbalance errors, waveform sampling errors, and phase shift errors.

The measurement errors may occur due to limitations in precision of the facility meters and transformers. The measurement errors may arise from factors including but not limiting to, sensor inaccuracies, environmental influences (e.g., temperature and humidity), and load conditions. The transformer may contribute to measurement errors through inaccuracies in the voltage and current transformation ratios. The measurement errors may be noticeable under varying load conditions or when non-linear loads may be present, which may distort the readings. Additionally, the measurement errors may include the accuracy class errors of the transformer 106 and the facility meters 110.

Accuracy class error may refer to deviation introduced by a meter due to its inherent design and operational limits as defined by the accuracy class of the meter. The accuracy class error may arise from factors such as measurement tolerances, environmental conditions (e.g., temperature and humidity), and load variations. The accuracy class error impacts the reliability of the recorded power consumption and must be considered when calculating or validating energy usage in a system. For instance, in a system involving multiple facility meters and transformers, the cumulative accuracy class errors of each component may influence the total power consumption calculations and comparisons. Proper evaluation and inclusion of these errors are essential to ensure precise energy validation and fault detection.

Furthermore, calibration errors may occur when the facility meters 110 or transformer 106 are not properly calibrated to the respective specified accuracy class. In facility meters 110, calibration errors may result from improper factory calibration, aging components, or drift in sensor accuracy over time. Transformers may exhibit calibration errors if the transformation ratios deviate from the nominal values due to aging, magnetic saturation, or incorrect settings during commissioning.

Voltage imbalance errors (voltage errors) may arise when there is a deviation between actual voltage supplied and voltage measured by the facility meters 110 or transformed by the transformer 106. In facility meters 110, the voltage errors may result from inadequate resolution or range of voltage sensors, leading to incorrect readings. In transformer 106, voltage errors may occur due to inaccuracies in the voltage transformation ratio, especially under varying load conditions or at low loads, where accuracy may degrade.

Waveform sampling errors may occur when there is an inaccurate representation of actual voltage or current waveform due to limitations in the sampling process of energy meters or related measurement devices. The waveform sampling errors may arise when the sampling rate, resolution, or synchronization of analog-to-digital converter (ADC) of the meter may be insufficient to capture the details of the waveform accurately, particularly in systems with high-frequency components, harmonic distortions, or rapidly changing loads.

Phase shift errors may be caused by misalignment between voltage and current waveforms, which directly affect power calculations, particularly for reactive and apparent power. In facility meters 110, phase shift errors may arise from imperfections in the internal circuitry, such as delays in sampling or signal processing. The transformer 106 may contribute to phase shift errors due to inductive or capacitive characteristics, magnetic flux leakage, or uneven loading conditions.

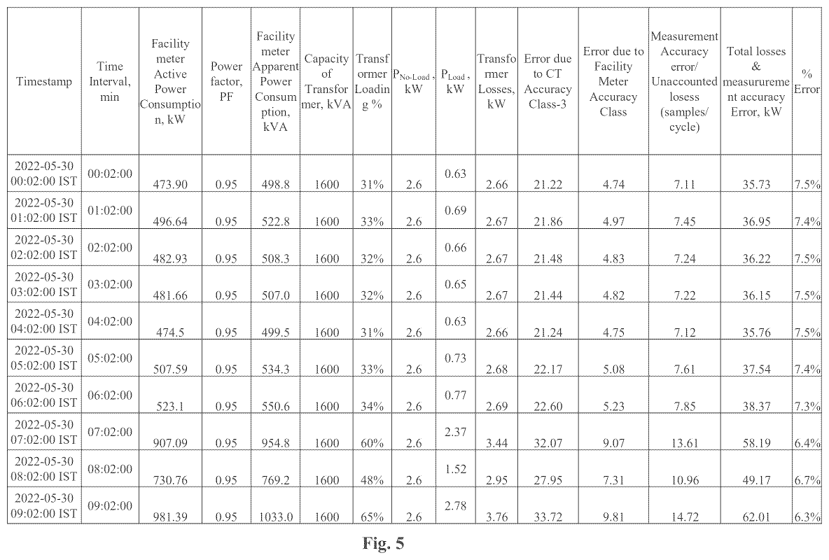

Further, in accordance with the present invention, the accuracy class errors of the facility meters 110 may be calculated based on the active power consumption of the loads and the accuracy class of each of the facility meters 110. As illustrated in FIG. 5, accuracy class error of the facility meter 110 may be calculated by multiplying the accuracy class of the facility meter 110 with the active power consumption recorded by the facility meter 110. The active power consumption may be divided by a power factor of the facility meter 110 connected to one or more electrical loads, to determine an apparent power consumption. Further, the apparent power consumption may be divided by capacity of the transformer 106 to provide a transformer loading %. The capacity of the transformer 106 may be retrieved from the one or more parameters associated with the transformer 106. Further, the losses associated with the transformer 106 may be calculated by using the eq. 1.

The losses associated with the transformer 106 and the one or more errors may be added to determine total losses and measurement accuracy error (KW) as shown in FIG. 5. Further, the total losses and measurement accuracy error may be divided by the active power consumption value recorded by the facility meter to determine an error percentage. In other words, adjusting the active power consumption value recorded by the facility meter with the total losses and measurement accuracy error may provide the power consumption of the facility 108.

In event 408, the system 102 may be configured to retrieve power consumption recorded by the utility meter 104 for the predetermined time period. The power consumption recorded by the utility meter 104 may be fetched via servers of electricity billing service (as shown in FIG. 1), or one or more electricity bills, or may be fetched manually if a user of the system 102 has access to the utility meter 104.

In event 410, the system 102 may be configured to generate a comparison between the power consumption of the facility 108 and the power consumption recorded by the utility meter 104 for the predetermined time period.

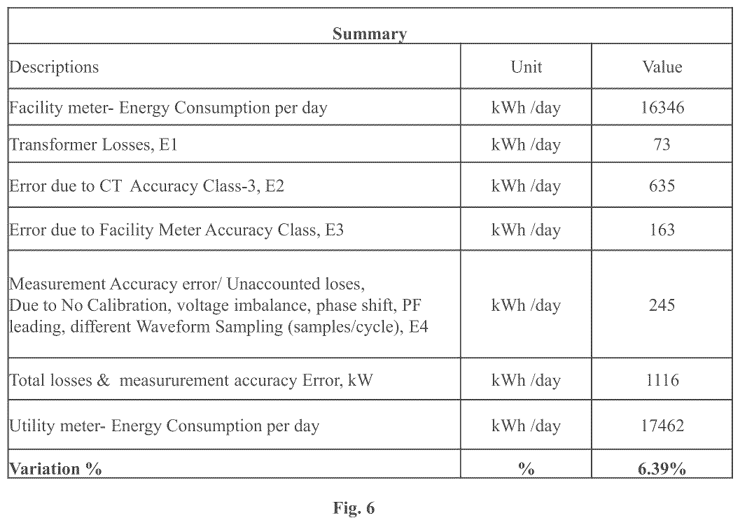

For example, in FIG. 6, a summary of the error calculations in FIG. 5 for the predetermined time is disclosed. The summary shows that variation between readings of a utility meter and the facility meter is approximately 6.39% and the total losses and measurement accuracy errors also amount to 6.39% of readings of the facility meter. Therefore, working conditions of the utility meter 104 and the facility meters 110, and the power consumption of the facility 108 are validated.

In event 412, the system 102 may be configured to store the comparison to validate and manage the power consumption at the facility 108. The comparison may be stored digitally in one or more formats depending on the requirements for accessibility, editing, or integration.

In one embodiment, the comparison may be stored in a Microsoft Word document (.docx) for using table structures for easy readability and editing. In another embodiment, the comparison may be stored in a Microsoft Excel spreadsheet (.xlsx) for advanced calculations and data manipulation. In one embodiment, the comparison may be represented as a relational database (e.g., SQL), allowing for structured querying and scalability. In another embodiment, the comparison may be stored in lightweight formats including but not limited to, JSON or XML for machine-readable applications. In one embodiment, for static or non-editable purposes, the comparison may be stored in a Portable Document Format (PDF) to ensure consistent formatting, or as a Comma-Separated Values (CSV) file for simple data exchange. In one embodiment, the comparison may be stored in HTML format for online display.

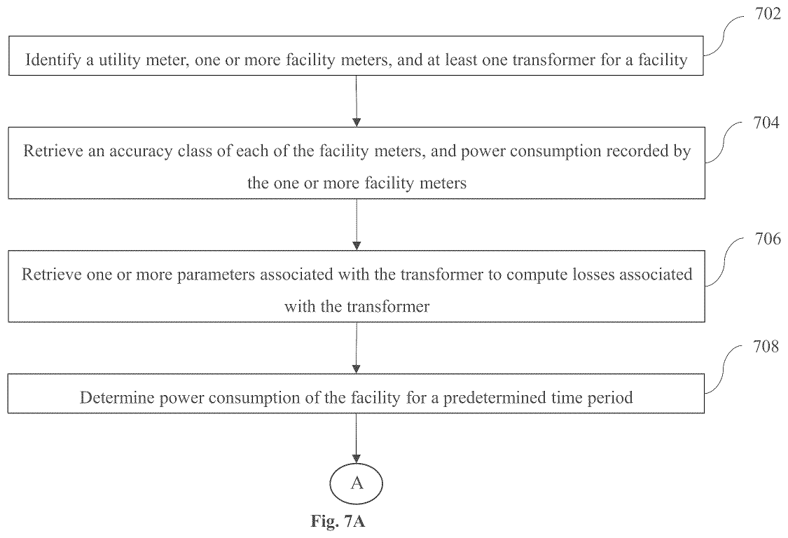

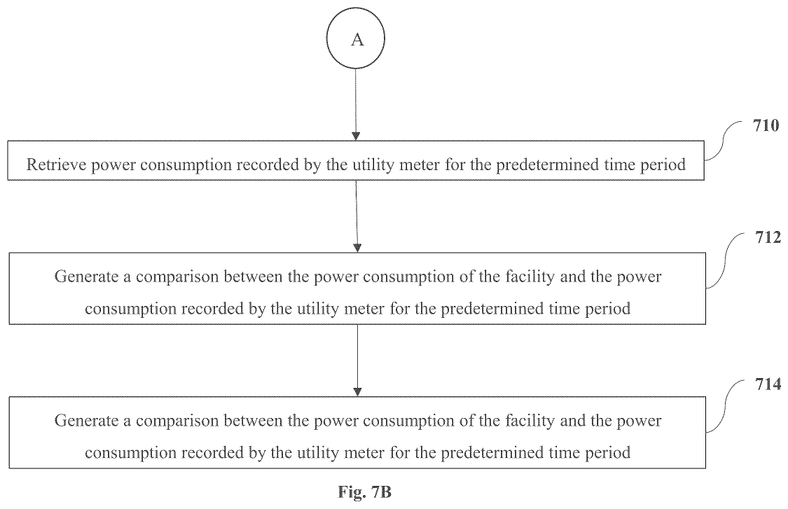

FIGS. 7A and 7B cumulatively illustrate a flow chart of a method for validating power consumption, in accordance with an embodiment of the present invention. In this regard, each block may represent a module, segment, or portion of code, which comprises one or more executable instructions for implementing the specified logical function(s). It should also be noted that in some alternative implementations, the functions noted in the blocks may occur out of the order noted in the drawings. For example, two blocks shown in succession in FIGS. 7A and 7B may in fact be executed substantially concurrently or the blocks may sometimes be executed in the reverse order, depending upon the functionality involved. Any process descriptions or blocks in flow charts should be understood as representing modules, segments, or portions of code which include one or more executable instructions for implementing specific logical functions or steps in the process, and alternate implementations are included within the scope of the example embodiments in which functions may be executed out of order from that shown or discussed, including substantially concurrently or in reverse order, depending on the functionality involved. In addition, the process descriptions or blocks in flow charts should be understood as representing decisions made by a hardware structure such as a state machine.

The order in which method is described is not intended to be construed as a limitation, and any number of the described method blocks can be combined in any order to implement the method. Additionally, individual blocks may be deleted from the methods without departing from the scope of the subject matter described herein.

Furthermore, the method can be implemented in any suitable hardware, software, firmware, or combination thereof. Furthermore, the above-mentioned methods may be implemented in suitable hardware, computer-readable instructions, or a combination thereof. The steps of such methods may be performed by either a system under the instruction of machine-executable instructions stored on a non-transitory computer-readable medium or by dedicated hardware circuits, microcontrollers, or logic circuits. The method may include the following steps.

At step 702, a utility meter, one or more facility meters, and at least one transformer may be identified for a facility. The transformer connects the utility meter to each facility meter, and each facility meter is connected to one or more loads. The utility meter may monitor consumption of a main supply power from a utility grid of a service provider. The facility meters may be distributed throughout the facility to monitor energy consumption.

At step 704, an accuracy class of each of the facility meters, and power consumption recorded by the one or more facility meters may be retrieved. The power consumption recorded by the facility meters may include but is not limited to, working power consumption, apparent power consumption, and power factors of one or more electrical loads connected to the facility meters. The accuracy class of a meter may refer to a predefined standard that specifies one or more permissible error limits of the meter under specified operating conditions.

At step 706, one or more parameters associated with the transformer may be retrieved to compute losses associated with the transformer. The one or more parameters associated with at least one transformer may include but are not limited to at least one of, transformer type, accuracy class of the transformer, number of transformers, and loading of the transformer.

The losses associated with the transformer may be attributed to transformer inefficiencies and may be calculated based on losses of the transformer on no load, full load, and partial load.

At step 708, power consumption of the facility may be determined for a predetermined time period. The power consumption of the facility may be determined by incorporating the losses associated with the transformer, and the one or more errors in the power consumption recorded by the one or more facility meters for the predetermined time period. The one or more errors further include one or more of, measurement errors, calibration errors, voltage imbalance errors, waveform sampling errors, and phase shift errors. Further, the measurement errors may occur due to limitations in precision of the facility meters and transformers, and may include the accuracy class errors of the transformer and the facility meters.

One or more sensors may be connected to the transformer. The sensor connected to the transformer may be configured to detect and transfer one or more parameters associated with transformer. In one embodiment, one or more sensors may be connected to the one or more facility meters. The sensor connected to the facility meters may be configured to detect and transfer data associated with working power consumption, apparent power consumption, and power factors of one or more electrical loads connected to the one or more facility meters.

The sensor connected to the transformer may have one or more accuracy class errors. Furthermore, the sensor connected to the facility meters may have one or more accuracy class errors. The accuracy class errors of the sensors may also be incorporated in the power consumption recorded by the facility meters, to determine the power consumption of the facility.

At step 710, power consumption recorded by the utility meter may be retrieved for the predetermined time period. The power consumption recorded by the utility meter may be fetched via servers of electricity billing service, or one or more electricity bills, or may be fetched manually if a user of the system has access to the utility meter.

At step 712, a comparison between the power consumption of the facility and the power consumption recorded by the utility meter may be generated for the predetermined time period.

At step 714, the comparison may be stored to validate and manage the power consumption at the facility. The comparison may be stored digitally in one or more formats depending on the requirements for accessibility, editing, or integration.

### Technical Advancement and Economic Significance

The method disclosed in the present invention for validating power consumption, may have the following advantages over conventional art:
Accurate validation of power consumption is ensured by accounting for transformer losses, facility meter accuracy class errors, and various measurement errors, such as calibration, voltage, and phase shift errors.
Discrepancies in energy data are eliminated by incorporating a comprehensive error analysis that addresses potential inaccuracies in both facility meters and transformers.
Early detection of faults in utility meters is ensured by identifying differences between the recorded utility meter consumption and the calculated power consumption of the facility.
Efficient energy planning is ensured by providing the capability to predict future energy consumption based on historical data and load patterns.
Need for extensive infrastructure modifications is eliminated by integrating seamlessly with existing energy monitoring systems.
Cost savings is ensured by reducing operational expenses through accurate energy monitoring, optimized consumption, and lower utility bills.
Unplanned downtimes and costly repairs are eliminated by enabling early detection of faults and potential equipment failures.
Inefficiencies in energy usage across diverse facilities, including industrial, commercial, residential, and institutional setups are eliminated, ensuring scalability and adaptability.

The specification may refer to “an”, “another”, “one” or “some” embodiment(s) in several locations.

This does not necessarily imply that each such reference is to the same embodiment(s), or that the feature only applies to a single embodiment. Single features of different embodiments may also be combined to provide other embodiments.

The terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps or acts are in some way inherently mutually exclusive.

As used herein, the singular forms “a”, “an” and “the” are intended to include the plural forms as well, unless expressly stated otherwise. It will be further understood that the terms “includes”, “comprises”, “including” and/or “comprising” when used in this specification, specify the presence of stated features, integers, steps, operations, elements, and/or components, but do not preclude the presence or addition of one or more other features, integers, steps, operations, elements, components, and/or groups thereof. It will be understood that when an element is referred to as being “connected” or “coupled” to another element, it can be directly connected or coupled to the other element or intervening elements may be present. Furthermore, “connected” or “coupled” as used herein may include operatively connected or coupled. As used herein, the term “and/or” includes any and all combinations and arrangements of one or more of the associated listed items.

Unless otherwise defined, all terms (including technical and scientific terms) used herein have the same meaning as commonly understood by one of ordinary skills in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Although implementations of a method for generating a system design have been described in language specific to structural features and/or methods, it is to be understood that the appended claims are not necessarily limited to the specific features or methods described. Rather, the specific features and methods are disclosed as examples of implementations of a method for generating a system design.

The invention has been described above with reference to numerous embodiments and specific examples. Many variations will suggest themselves to those skilled in this art in light of the above-detailed description. All such obvious variations are within the full intended scope of the appended claims.

We claim:

1. A method for validating power consumption, comprising:
identifying, for a facility, a utility meter, one or more facility meters, and at least one transformer, wherein the transformer connects the utility meter to each facility meter, and each facility meter is connected to one or more loads;
retrieving an accuracy class of each of the facility meters, and power consumption recorded by the one or more facility meters;
retrieving one or more parameters associated with the transformer to compute losses associated with the transformer;
determining power consumption of the facility for a predetermined time period, based on factors including power consumption recorded by the facility meters, the losses associated with the transformer and one or more errors including accuracy class errors of each facility meter based on loads, and accuracy class errors associated with the transformer;
retrieving power consumption recorded by the utility meter for the predetermined time period;
generating a comparison between the power consumption of the facility and the power consumption recorded by the utility meter for the predetermined time period; and
storing the comparison for validating and managing power consumption at the facility.

2. The method as claimed in claim 1, wherein the power consumption recorded by the facility meters includes at least one of active power consumption and apparent power consumption of the loads connected to the facility meters and power factors of the loads.

3. The method as claimed in claim 1, wherein the accuracy class errors of the facility meters are calculated based on the active power consumption of the loads and the accuracy class of each of the facility meters.

4. The method as claimed in claim 1, wherein the one or more parameters associated with the transformer include at least one of transformer type, accuracy class of the transformer, number of transformers, and loading of the transformer.

5. The method as claimed in claim 1, wherein the losses associated with the transformer are calculated based on losses of the transformer on no load, full load, and partial load.

6. The method as claimed in claim 1, wherein the one or more errors further include one or more of measurement errors, calibration errors, voltage errors, waveform sampling errors, and phase shift errors.

7. The method as claimed in claim 1, wherein the accuracy class of the facility meters, and the transformer are pre-defined.

8. The method as claimed in claim 1, further comprising:
detecting a fault in operation of the utility meter upon determining a difference in the power consumption recorded by the utility meter and the power consumption of the facility for the predetermined time period.

9. The method as claimed in claim 1, further comprising:
predicting future power consumption by the one or more loads, using the power consumption of the facility for the predetermined time period.

10. A system for validating power consumption, comprises:
a processor; and
a memory coupled with the processor, wherein the memory stores program instructions configured to:
identify a utility meter, one or more facility meters, and at least one transformer for a facility, wherein the transformer connects the utility meter to each facility meter, and each facility meter is connected to one or more loads;
retrieve an accuracy class of each of the facility meters, and power consumption recorded by the one or more facility meters;
retrieve one or more parameters associated with the transformer to compute losses associated with the transformer;
determine power consumption of the facility for a predetermined time period, based on factors including power consumption recorded by the one or more facility meters, the losses associated with the transformer and one or more errors including accuracy class errors of each facility meter based on loads, and accuracy class errors associated with the transformer;
retrieve power consumption recorded by the utility meter for the predetermined time period;
generate a comparison between the power consumption of the facility and the power consumption recorded by the utility meter for the predetermined time period; and
store the comparison to validate and manage power consumption at the facility.

11. The system as claimed in claim 10, wherein the power consumption recorded by the facility meters includes at least one of active power consumption and apparent power consumption of the loads connected to the facility meters, and power factors of the loads.

12. The system as claimed in claim 10, wherein the accuracy class errors of the facility meters are calculated based on the active power consumption of the loads and an accuracy class of each of the facility meters.

13. The system as claimed in claim 10, wherein the one or more parameters associated with at least one transformer include at least one of transformer type, accuracy class of the transformer, number of transformers, and loading of the transformer.

14. The system as claimed in claim 10, wherein the losses associated with the transformer are calculated based on losses of the transformer on no load, full load, and partial load.

15. The system as claimed in claim 10, wherein the one or more errors further include one or more of measurement errors, calibration errors, voltage errors, and phase shift errors.

16. The system as claimed in claim 10, wherein the accuracy class of the facility meters, and the transformer are pre-defined.

17. The system as claimed in claim 10, wherein the memory further stores program instructions configured to detect a fault in operation of the utility meter upon determining a difference in the power consumption recorded by the utility meter and the power consumption of the facility for the predetermined time period.

18. The system as claimed in claim 10, wherein the memory further stores program instructions configured to predict future energy consumptions by the one or more loads, using the power consumption of the facility for the predetermined time period.

19. A non-transitory computer-readable storage medium comprising computer program code for execution by one or more processors of an apparatus, the computer program code configured to, when executed by the one or more processors, cause the apparatus to:
identify a utility meter, one or more facility meters, and at least one transformer for a facility, wherein the transformer connects the utility meter to each facility meter, and each facility meter is connected to one or more loads;
retrieve an accuracy class of each of the facility meters, and power consumption recorded by the one or more facility meters;
retrieve one or more parameters associated with the transformer to compute losses associated with the transformer;
determine power consumption of the facility for a predetermined time period, based on factors including power consumption recorded by the facility meters, the losses associated with the transformer and one or more errors including accuracy class errors of each facility meter based on loads, and accuracy class errors associated with the transformer;
retrieve power consumption recorded by the utility meter for the predetermined time period;
generate a comparison between the power consumption of the facility and the power consumption recorded by the utility meter for the predetermined time period; and
store the comparison to validate and manage power consumption at the facility.

20. The non-transitory computer-readable storage medium as claimed in claim 19, wherein the losses associated with the transformer are calculated based on losses of the transformer on no load, full load, and partial load.
